(19) United States
(12) Patent Application Publication
(10) Pub. No.: US 2015/0217989 A1
(43) Pub. Date: Aug. 6, 2015

(54) MEMS DEVICE, PRESSURE SENSOR, ALTIMETER, ELECTRONIC APPARATUS, AND MOVING OBJECT

(71) Applicant: Seiko Epson Corporation, Tokyo (JP)

(72) Inventor: Yusuke MATSUZAWA, Chino (JP)

(21) Appl. No.: 14/601,615

(22) Filed: Jan. 21, 2015

(30) Foreign Application Priority Data
Jan. 31, 2014 (JP) 2014-018074

(51) Int. Cl. B81B 3/00

(52) U.S. Cl. CPC B81B 3/0054; B81B 2201/0264; B81B 2201/0292

(57) ABSTRACT

A MEMS device includes: a substrate; a sensor element (functional element) that is disposed above the substrate; a surrounding wall that is disposed above one surface side of the substrate and surrounds the sensor element in a plan view; a covering layer that overlaps the substrate in the plan view and is connected to the surrounding wall; and a reinforcing layer that is arranged between the covering layer and the sensor element. The surrounding wall includes a substrate-side surrounding wall, and a covering layer-side surrounding wall that is located on the covering layer side of the substrate-side surrounding wall and at least a portion of which is disposed above the inside of the substrate-side surrounding wall in the plan view.

### BACKGROUND

1. Technical Field

The present invention relates to a MEMS device, a pressure sensor, an altimeter, an electronic apparatus, and a moving object.

2. Related Art

In recent years, electronic devices, such as sensors, resonators, or communication devices, including a MEMS element on a semiconductor substrate using micro electro mechanical system (MEMS) technology have attracted attention. As such an electronic device, an electronic device including a substrate, a MEMS element formed on the substrate, a surrounding wall provided on the substrate and surrounding the MEMS element, and a covering portion covering the MEMS element from above has been known (for example, refer to JP-A-2008-114354). The electronic device is very small. Particularly the covering portion covering the MEMS element from above is formed to be thin from the viewpoint of miniaturization.

However, the electronic device having the configuration described above has a problem in that since the covering portion is formed to be thin, the covering portion sags toward the MEMS element side and the covering portion contacts the MEMS element in, for example, the manufacture or use of the electronic device. As a result, the characteristics of the MEMS element become unstable.

Moreover, it is considered that such a MEMS device is used as a pressure sensor. As the pressure sensor, for example, a pressure sensor configured to include a diaphragm is considered. The diaphragm, which is deflected and deformed under pressure, is obtained by thinning a substrate by forming a recess in the substrate, and the portion thinned with the recess serves as the diaphragm. As the pressure sensor having the configuration described above, for example, FIGS. 16A and 16B show cross-sectional views of a pressure sensor including a diaphragm.

As shown in FIG. 16A, the pressure sensor 9 includes a substrate 91, a diaphragm 93 as a thinned portion that is thinned with a recess 92 formed in the substrate 91, a sensor element 94 provided on the diaphragm 93, a surrounding wall 95 surrounding the sensor element 94, and a covering layer 96 provided so as to cover over the sensor element 94. In the pressure sensor 9, deflection of the diaphragm 93 is detected by the sensor element 94, whereby a pressure applied to the diaphragm 93 can be detected. For this reason, in the pressure sensor 9, as the amount of deflection of the diaphragm 93 becomes large, the sensitivity of the pressure sensor 9 can be increased. Therefore, for increasing the amount of deflection of the diaphragm 93, it is considered to increase the plane area of the diaphragm 93 and reduce the thickness of the diaphragm 93.

However, when the plane area of the diaphragm 93 is intended to be increased, the plan-view shape of an inner wall surface 951 of the surrounding wall 95 becomes large as the plane area increases, and thus, the plane area of the covering layer 96 is also increased. As a result, the pressure sensor 9 having the configuration described above has a problem in that the covering layer 96 further sags toward the sensor element 94 side and the covering layer 96 contacts the sensor element 94 as shown in FIG. 16B.

### SUMMARY

An advantage of some aspects of the invention is to provide a MEMS device in which contacting of a covering layer with a functional element can be reduced, a pressure sensor, an altimeter, an electronic apparatus, and a moving object.

The invention can be implemented as the following application examples.

### Application Example 1

This application example is directed to a MEMS device including: a substrate; a functional element that is disposed above the substrate; a surrounding wall that is disposed above one surface side of the substrate and surrounds the functional element in a plan view; a covering layer that overlaps the substrate in the plan view and is connected to the surrounding wall; and a reinforcing layer that is arranged between the covering layer and the functional element, wherein the surrounding wall includes a substrate-side surrounding wall, and a covering layer-side surrounding wall that is located on the covering layer side of the substrate-side surrounding wall and at least a portion of which is disposed above the inside of the substrate-side surrounding wall in the plan view.

With this configuration, the plane area of the covering layer can be reduced while securing a region of the substrate where the functional element is arranged, and thus, sagging of the covering layer toward the substrate side can be reduced. Therefore, it is possible to provide the MEMS device in which contacting of the covering layer with the functional element is reduced.

### Application Example 2

In the MEMS device according to the application example described above, it is preferable that the reinforcing layer includes a through-hole that penetrates the reinforcing layer in a thickness direction thereof.

With this configuration, the mechanical strength of the covering layer can be reinforced, and the mass of the reinforcing layer can be reduced. Therefore, contacting of the covering layer with the functional element caused by sagging of the covering layer toward the substrate side can be reduced, and sagging of the reinforcing layer under its own weight toward the substrate side can be reduced.

### Application Example 3

In the MEMS device according to the application example described above, it is preferable that the reinforcing layer is connected to the covering layer.

With this configuration, the mechanical strength of the covering layer in the thickness direction can be increased, and thus, contacting of the covering layer with the functional element can be more effectively reduced.

### Application Example 4

In the MEMS device according to the application example described above, it is preferable that the substrate includes a diaphragm portion that is deflected and deformed under pressure and at least a portion of which overlaps the covering layer in the plan view.

With this configuration, the diaphragm portion can be deformed in response to the application of a pressure, and the deformation is detected by the functional element, whereby the pressure applied to the diaphragm portion can be detected.

### Application Example 5

In the MEMS device according to the application example described above, it is preferable that at least a portion of the functional element overlaps the covering layer-side surrounding wall in the plan view.

With this configuration, even if the covering layer should sag toward the substrate side, contacting of the covering layer with the functional element can be more effectively reduced.

### Application Example 6

In the MEMS device according to the application example described above, it is preferable that the functional element includes a piezoresistive element.

With this configuration, it becomes easy to arrange the functional element such that at least a portion of the functional element overlaps the covering layer-side surrounding wall in the plan view. Therefore, even if the covering layer should sag toward the substrate side, contacting of the covering layer with the functional element can be further effectively reduced.

### Application Example 7

In the MEMS device according to the application example described above, it is preferable that the plan-view shape of the reinforcing layer includes a grid-like portion.

With this configuration, the mechanical strength of the covering layer in the thickness direction can be further increased, and thus, sagging of the covering layer toward the substrate side can be further effectively reduced.

### Application Example 8

This application example is directed to a pressure sensor including the MEMS device according to the application example described above.

With this configuration, it is possible to provide the pressure sensor having high reliability.

### Application Example 9

This application example is directed to an altimeter including the MEMS device according to the application example described above.

With this configuration, it is possible to provide the altimeter having high reliability.

### Application Example 10

This application example is directed to an electronic apparatus including the MEMS device according to the application example described above.

With this configuration, it is possible to provide the electronic apparatus having high reliability.

### Application Example 11

This application example is directed to a moving object including the MEMS device according to the application example described above.

With this configuration, it is possible to provide the moving object having high reliability.

### BRIEF DESCRIPTION OF THE DRAWINGS

The invention will be described with reference to the accompanying drawings, wherein like numbers reference like elements.

FIG. 1 is a cross-sectional view showing a first embodiment of a pressure sensor including a MEMS device according to the invention.

FIG. 2 is a plan view (viewed from a direction of the arrow B in FIG. 1) of the pressure sensor shown in FIG. 1.

FIG. 3 is an enlarged plan view (cross-sectional view taken along the line A-A in FIG. 1) of a diaphragm portion and its vicinity of the pressure sensor shown in FIG. 1.

FIG. 4 is a diagram showing a bridge circuit including a sensor element (piezoresistive element) shown in FIG. 1.

FIGS. 5A and 5B are diagrams for explaining the action of the pressure sensor shown in FIG. 1, in which FIG. 5A is a cross-sectional view showing a pressurized state, and FIG. 5B is a plan view showing the pressurized state.

FIGS. 6A to 6E are diagrams showing manufacturing steps of the pressure sensor shown in FIG. 1.

FIGS. 7A to 7C are diagrams showing manufacturing steps of the pressure sensor shown in FIG. 1.

FIGS. 8A to 8C are diagrams showing manufacturing steps of the pressure sensor shown in FIG. 1.

FIGS. 9A and 9B are diagrams showing manufacturing steps of the pressure sensor shown in FIG. 1.

FIGS. 10A and 10B are cross-sectional views showing a second embodiment of the pressure sensor including the MEMS device according to the invention.

FIGS. 11A and 11B are cross-sectional views showing a third embodiment of the pressure sensor including the MEMS device according to the invention.

FIGS. 12A and 12B are cross-sectional views showing a fourth embodiment of the pressure sensor including the MEMS device according to the invention.

FIG. 13 is a perspective view showing an example of an altimeter according to the invention.

FIG. 14 is an elevation view showing an example of an electronic apparatus according to the invention.

FIG. 15 is a perspective view showing an example of a moving object according to the invention.

FIGS. 16A and 16B are cross-sectional views showing a pressure sensor including a diaphragm.

### DESCRIPTION OF EXEMPLARY EMBODIMENTS

Hereinafter, a MEMS device, a pressure sensor, an altimeter, an electronic apparatus, and a moving object according to the invention will be described in detail based on embodiments shown in the accompanying drawings.

### 1. Pressure Sensor

### First Embodiment

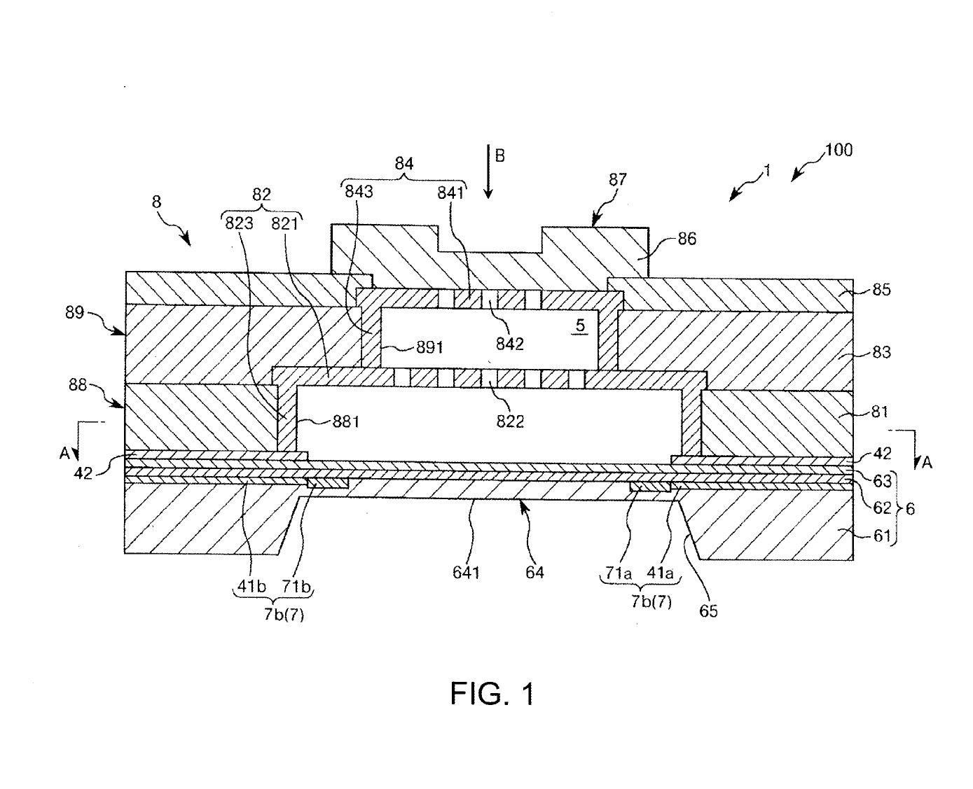

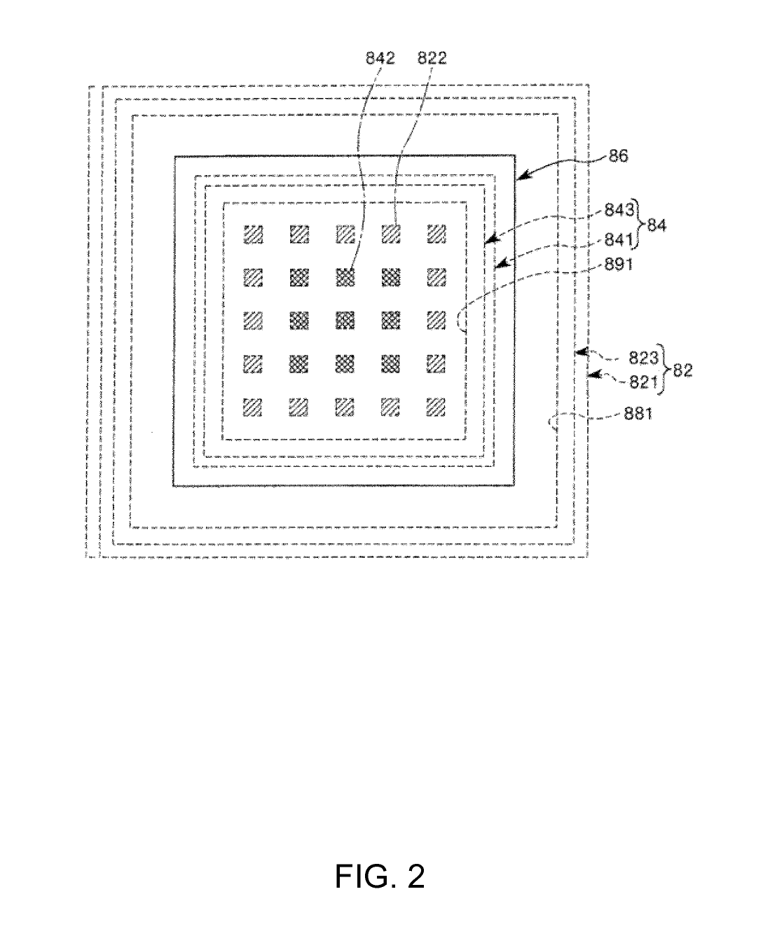

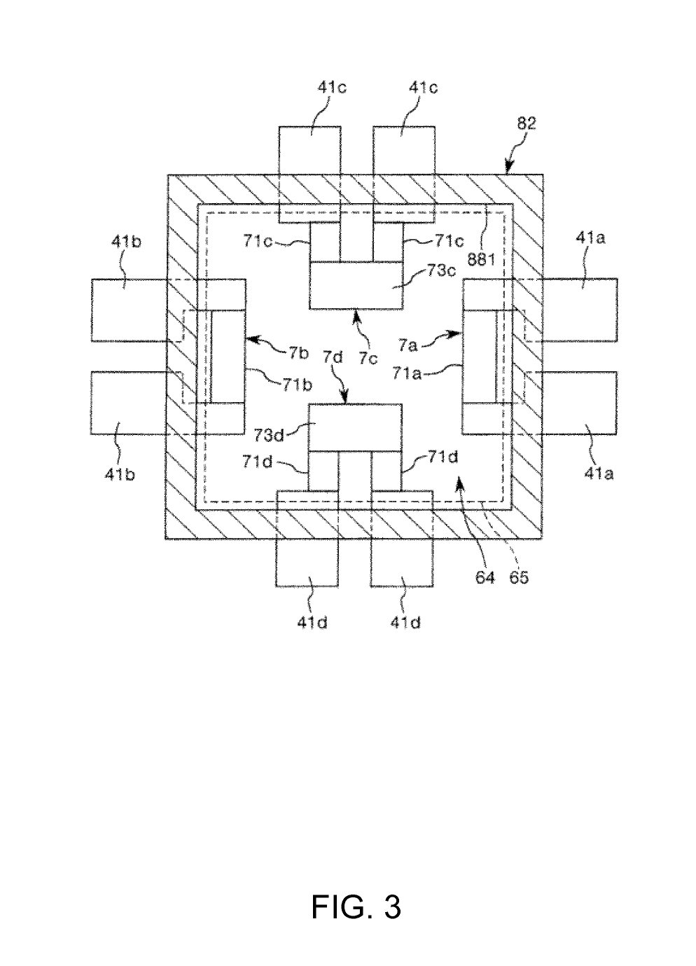

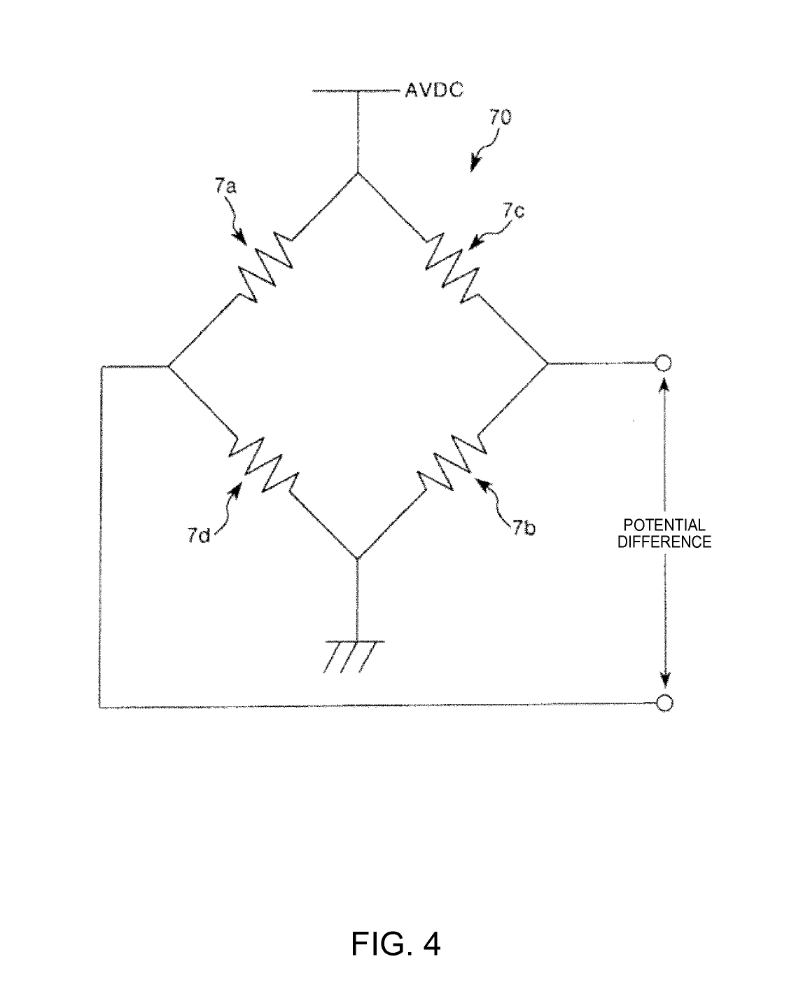

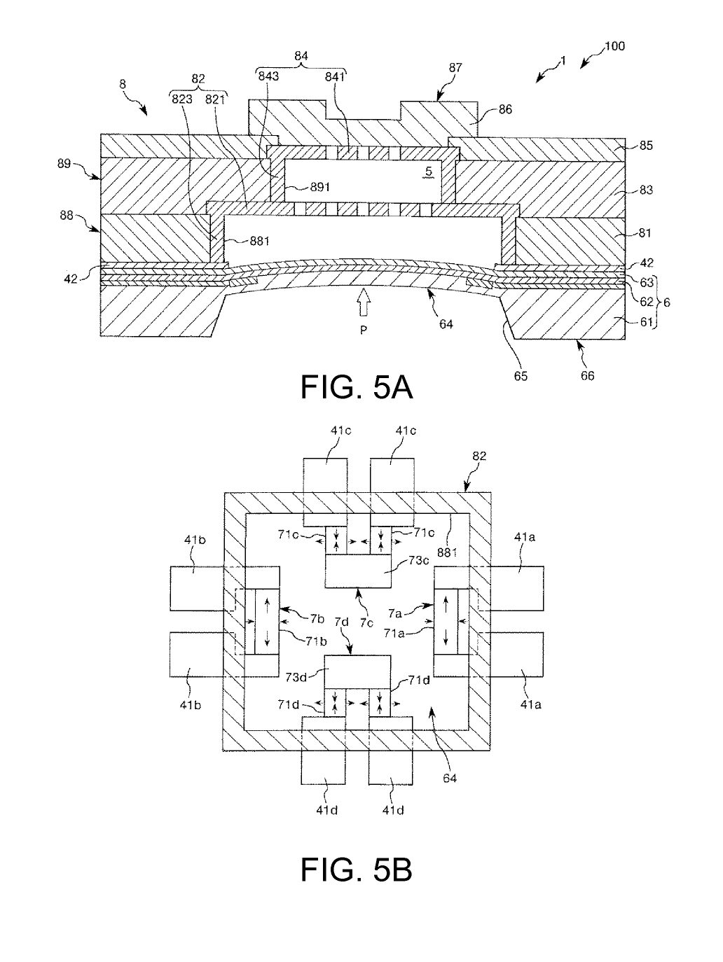

FIG. 1 is a cross-sectional view showing a first embodiment of a pressure sensor including a MEMS device according to the invention. FIG. 2 is an enlarged plan view of a diaphragm portion and its vicinity of the pressure sensor shown in FIG. 1. FIG. 3 is an enlarged plan view (cross-sectional view taken along the line A-A in FIG. 1) of the diaphragm portion and its vicinity of the pressure sensor shown in FIG. 1. FIG. 4 is a diagram showing a bridge circuit including a sensor element (piezoresistive element) included in the pressure sensor shown in FIG. 1. FIGS. 5A and 5B are diagrams for explaining the action of the pressure sensor shown in FIG. 1, in which FIG. 5A is a cross-sectional view showing a pressurized state, and FIG. 5B is a plan view showing the pressurized state. In FIG. 3, for convenience of description, an inter-layer insulating film 81, a layer 42, and a substrate 6 are not shown.

A pressure sensor 100 shown in FIG. 1 includes the substrate 6, a sensor element 7, an element peripheral structure 8, and a cavity portion 5 (cavity). The pressure sensor 100 from which a diaphragm portion 64 provided on the substrate 6 described later is omitted constitutes a MEMS device 1 (MEMS device according to the invention).

Hereinafter, these parts will be sequentially described.

### Substrate 6

The substrate 6 has a plate shape, and is composed of a semiconductor substrate 61 composed of semiconductor such as monocrystalline silicon, a silicon oxide film 62 provided on one of surfaces of the semiconductor substrate 61, and a silicon nitride film 63 provided on the silicon oxide film 62. The plan-view shape of the substrate 6 is not particularly limited, and the shape can be a rectangle such as, for example, a substantially square shape or a substantially oblong shape, or a circle. Both the silicon oxide film 62 and the silicon nitride film 63 can be used as insulating films. One of these insulating films can be omitted depending on a forming method of the element peripheral structure 8, or the like.

In the substrate 6, the diaphragm portion 64, which is thinner than the peripheral portion and deflected and deformed under pressure, is provided. The diaphragm portion 64 is formed by providing a bottomed recess 65 in a lower surface of the substrate 6. A lower surface of the diaphragm portion 64 is a pressure receiving surface 641.

As shown in FIG. 3, the plan-view shape of the diaphragm portion 64 is square. The plan-view shape of the diaphragm portion 64 corresponds to the shape of the recess 65 described above and the shape of an inner wall surface 881 of a substrate-side surrounding wall 88 described later.

### Sensor Element 7

As shown in FIG. 3, the sensor element 7 is composed of a plurality of (four in the embodiment) piezoresistive elements 7a, 7b, 7c, and 7d provided in the diaphragm portion 64 of the substrate 6.

The piezoresistive elements 7a and 7b are provided corresponding to one of pairs of facing sides (arranged in the horizontal direction in FIG. 3 and hereinafter also referred to as “first sides”) of the diaphragm portion 64 having a quadrilateral shape in a plan view in the thickness direction of the substrate 6. The piezoresistive elements 7c and 7d are provided corresponding to the other pair of facing sides (arranged in the vertical direction in FIG. 3 and hereinafter also referred to as “second sides”) of the diaphragm portion 64 having the quadrilateral shape in the plan view.

The piezoresistive element 7a includes a piezoresistive portion 71a provided in the vicinity of a perimeter portion (more specifically, the vicinity of the right first side in FIG. 3) of the diaphragm portion 64. The piezoresistive portion 71a has a longitudinal shape extending along a direction parallel to the first side. Wires 41a are respectively connected to both ends of the piezoresistive portion 71a.

Similarly, the piezoresistive element 7b includes a piezoresistive portion 71b provided in the vicinity of the perimeter portion (more specifically, the vicinity of the left first side in FIG. 3) of the diaphragm portion 64. Wires 41b are respectively connected to both ends of the piezoresistive portion 71b.

On the other hand, the piezoresistive element 7c includes a pair of piezoresistive portions 71c provided in the vicinity of the perimeter portion (more specifically, the vicinity of the upper second side in FIG. 3) of the diaphragm portion 64, and a connecting portion 73c connecting the pair of piezoresistive portions 71c to each other. The pair of piezoresistive portions 71c are parallel to each other and each have a longitudinal shape extending along a direction vertical to the second side (that is, a direction parallel to the first side). One ends (ends on the center side of the diaphragm portion 64) of the pair of piezoresistive portions 71c are connected to each other via the connecting portion 73c. Wires 41c are respectively connected to the other ends (ends on the perimeter side of the diaphragm portion 64) of the pair of piezoresistive portions 71c.

Similarly, the piezoresistive element 7d includes a pair of piezoresistive portions 71d provided in the vicinity of the perimeter portion (more specifically, the vicinity of the lower second side in FIG. 3) of the diaphragm portion 64, and a connecting portion 73d connecting the pair of piezoresistive portions 71d to each other. One ends (ends on the center side of the diaphragm portion 64) of the pair of piezoresistive portions 71d are connected to each other via the connecting portion 73d. Wires 41d are respectively connected to the other ends (ends on the perimeter side of the diaphragm portion 64) of the pair of piezoresistive portions 71d.

The piezoresistive portions 71a, 71b, 71c, and 71d are composed of, for example, polysilicon (polycrystalline silicon) into which an impurity such as phosphorus or boron is doped (diffused or implanted). The connecting portions 73c and 73d of the piezoresistive elements 7c and 7d and the wires 41a, 41b, 41c, and 41d are each formed of, for example, polysilicon (polycrystalline silicon) into which an impurity such as phosphorus or boron is doped (diffused or implanted) at a higher concentration than the piezoresistive portions 71a, 71b, 71c, and 71d.

The piezoresistive elements 7a, 7b, 7c, and 7d are configured such that the resistance values in a natural state are equal to each other. The piezoresistive elements 7a, 7b, 7c, and 7d are electrically connected to each other via the wires 41a, 41b, 41c, and 41d or the like to constitute a bridge circuit 70 (Wheatstone bridge circuit) as shown in FIG. 4. A driver circuit (not shown) that supplies a drive voltage AVDC is connected to the bridge circuit 70. The bridge circuit 70 outputs a signal (voltage) according to the resistance value of the piezoresistive elements 7a, 7b, 7c, and 7d.

Even when the diaphragm portion 64 that is extremely thin as described above is used, the sensor element 7 does not suffer from a problem of reduced Q value caused by vibration leakage to the diaphragm portion 64 as in the case where a vibrating element such as a resonator is used as a sensor element.

### Element Peripheral Structure 8

As shown in FIG. 1, the element peripheral structure 8 is formed so as to define the cavity portion 5 where the sensor element 7 is arranged.

The element peripheral structure 8 includes: the inter-layer insulating film 81 formed on the substrate 6 so as to surround the sensor element 7; a wiring layer 82 formed on the inter-layer insulating film 81; an inter-layer insulating film 83 formed on the wiring layer 82 and the inter-layer insulating film 81; a wiring layer 84 formed on the inter-layer insulating film 83; a surface protective layer 85 formed on the wiring layer 84 and the inter-layer insulating film 83; and a sealing layer 86 provided on the wiring layer 84. The wiring layer 84 includes a shielding layer 841 including a plurality of fine pores (through-holes) 842. The sealing layer 86 is provided so as to close the through-holes 842.

A layer 42 composed of, for example, polycrystalline silicon or the like is provided between the wiring layer 82 and the silicon nitride film 63. The layer 42 is formed together with the sensor element 7 and the substrate 6 as described later, but may be omitted as necessary.

In the element peripheral structure 8 having the configuration described above, the inter-layer insulating film 81 and the wiring layer 82 constitute the substrate-side surrounding wall 88; the inter-layer insulating film 83 and the wiring layer 84 (only a side wall portion 843 as a portion of the wiring layer 84 except for the shielding layer 841) constitute a covering layer-side surrounding wall 89; and the shielding layer 841 included in the wiring layer 84 and the sealing layer 86 constitute a covering layer 87 that covers the sensor element 7 from above.

A semiconductor circuit (not shown) is fabricated on and above the semiconductor substrate 61. The semiconductor circuit includes circuit elements such as active elements including a MOS transistor formed as necessary, capacitors, inductors, resistors, diodes, and wires (including the wires connected to the sensor element 7).

Since the element peripheral structure 8 is one of features of the pressure sensor 100, a detailed configuration of the element peripheral structure 8 will be described in detail later.

### Cavity Portion 5

The cavity portion 5 defined by the substrate 6 and the element peripheral structure 8 functions as an accommodating portion (cavity) that accommodates the sensor element 7. That is, the cavity portion 5 is a hermetically sealed space, and the sensor element 7 is surrounded by the substrate 6, the substrate-side surrounding wall 88, the covering layer-side surrounding wall 89, and the covering layer 87. For this reason, the sensor element 7 can be protected from the outside, so that the deterioration or characteristic variations of the sensor element 7 can be reduced. Moreover, the inside of the cavity portion 5 functions as a pressure reference chamber serving as a reference value of pressure that the pressure sensor 100 detects.

In the embodiment, the cavity portion 5 is in a vacuum state (300 Pa or less). By bringing the cavity portion 5 into the vacuum state, the pressure sensor 100 can be used as an “absolute pressure sensor” that detects a pressure with the vacuum state as a reference, so that the convenience of the pressure sensor is improved.

However, the cavity portion 5 may not be in the vacuum state, and may be in an atmospheric pressure, a reduced-pressure state where the air pressure is lower than the atmospheric pressure, or a pressurized state where the air pressure is higher than the atmospheric pressure. Moreover, an inert gas such as nitrogen gas or noble gas may be sealed in the cavity portion 5.

The configuration of the pressure sensor 100 has been briefly described above.

In the pressure sensor 100 having the configuration described above, the diaphragm portion 64 is deformed in response to a pressure received by the pressure receiving surface 641 of the diaphragm portion 64 as shown in FIG. 5A. With the deformation, the piezoresistive elements 7a, 7b, 7c, and 7d strain as shown in FIG. 5B, so that the resistance value of the piezoresistive elements 7a, 7b, 7c, and 7d changes. With the change, an output of the bridge circuit 70 (refer to FIG. 4) composed of the piezoresistive elements 7a, 7b, 7c, and 7d changes, and based on the output, the magnitude of the pressure received by the pressure receiving surface 641 can be obtained.

This will be described more specifically. As described above, since the resistance values of the piezoresistive elements 7a, 7b, 7c, and 7d are equal to each other, the product of the resistance values of the piezoresistive elements 7a and 7b is equal to the product of the resistance values of the piezoresistive elements 7c and 7d in the natural state before the occurrence of the above-described deformation of the diaphragm portion 64, so that the output (potential difference) of the bridge circuit 70 is zero.

On the other hand, as shown in FIG. 5B, when the above-described deformation of the diaphragm portion 64 occurs, tensile strain along the longitudinal direction and compressive strain along the width direction occur in the piezoresistive portions 71a and 71b of the piezoresistive elements 7a and 7b while compressive strain along the longitudinal direction and tensile strain along the width direction occur in the piezoresistive portions 71c and 71d of the piezoresistive elements 7c and 7d.

In this case, due to the above-described deformation of the diaphragm portion 64, the piezoresistive portions 71a and 71b receive compressive force in the width direction, but tensile strain occurs in the piezoresistive portions 71a and 71b along the longitudinal direction according to the Poisson's ratio of the piezoresistive portions 71a and 71b. Moreover, due to the above-described deformation of the diaphragm portion 64, the piezoresistive portions 71c and 71d receive compressive force in the longitudinal direction, and in response to the compressive force, compressive strain occurs in the piezoresistive portions 71c and 71d along the longitudinal direction.

Due to the strain of the piezoresistive portions 71a, 71b, 71c, and 71d, a difference is generated between the product of the resistance values of the piezoresistive elements 7a and 7b and the product of the resistance values of the piezoresistive elements 7c and 7d, and an output according to the difference (potential difference) is output from the bridge circuit 70. Based on the output from the bridge circuit 70, the magnitude of the pressure (absolute pressure) received by the pressure receiving surface 641 can be obtained.

In this case, when the above-described deformation of the diaphragm portion 64 occurs, the resistance values of the piezoresistive elements 7a and 7b are increased, and the resistance values of the piezoresistive elements 7c and 7d are reduced. Therefore, it is possible to increase a change in difference between the product of the resistance values of the piezoresistive elements 7a and 7b and the product of the resistance values of the piezoresistive elements 7c and 7d. With the increase in change, the output from the bridge circuit 70 can be increased. As a result, detection sensitivity for pressure can be increased. Moreover, since all of the piezoresistive elements 7a, 7b, 7c, and 7d constituting the bridge circuit 70 have substantially the same temperature sensitivity, it is also possible to reduce a characteristic change to an external temperature change.

In the pressure sensor 100 having the configuration described above, contacting of the covering layer 87 with the sensor element 7 due to sagging toward the cavity portion 5 side can be reduced through the contrivance of the configuration of the element peripheral structure 8. Hereinafter, this will be described in detail.

As described above, the element peripheral structure 8 includes the substrate-side surrounding wall 88, the covering layer-side surrounding wall 89, and the covering layer 87.

As shown in FIG. 1, the substrate-side surrounding wall 88 is composed of the inter-layer insulating film 81 and the wiring layer 82.

The inter-layer insulating film 81 has a quadrilateral frame shape in the plan view, and is provided so as to surround the sensor element 7 (refer to FIG. 2). A lower opening of the inter-layer insulating film 81 is closed by the substrate 6.

The wiring layer 82 is provided on the inter-layer insulating film 81. The wiring layer 82 includes a reinforcing layer 821 provided so as to close an upper opening of the inter-layer insulating film 81 and cross the cavity portion 5.

As shown in FIG. 2, the plan-view shape of the reinforcing layer 821 is a quadrilateral, and the reinforcing layer 821 includes a plurality of (25 in the embodiment) through-holes 822 at the center portion. In FIG. 2, the through-holes 822 are shown by hatching.

The through-hole 822 penetrates the reinforcing layer 821 in the thickness direction. The plan-view shape of the through-hole 822 is a quadrilateral. The through-holes 822 are provided in a 5×5 matrix and parallel to outer edges of the reinforcing layer 821. The through-holes 822 are spaced apart from each other with a predetermined distance, and arranged such that spaced apart distances each between the through-hole 822 and the closest through-hole 822 are equal to each other. The arrangement, number, shape, and the like of the through-holes 822 are not limited to those described above.

The covering layer-side surrounding wall 89 is provided on the covering layer 87 side of the substrate-side surrounding wall 88 having the configuration described above.

The covering layer-side surrounding wall 89 is composed of the inter-layer insulating film 83 and the wiring layer 84 (only the side wall portion 843 except for the shielding layer 841).

The inter-layer insulating film 83 is provided on the inter-layer insulating film 81. The inter-layer insulating film 83 has a quadrilateral frame shape in the plan view, and is provided so as to surround the sensor element 7.

An entire inner wall surface of the inter-layer insulating film 83 is provided so as to be contained in an inner wall surface of the inter-layer insulating film 81 in the plan view. The side wall portion 843 except for the shielding layer 841 has an annular shape in the plan view, and is located on the inside of the inter-layer insulating film 83. Therefore, an entire inner wall surface 891 of the covering layer-side surrounding wall 89 having the configuration described above is contained in an inner wall surface 881 of the substrate-side surrounding wall 88 in the plan view.

The covering layer-side surrounding wall 89 is arranged so as to cover the piezoresistive portions 71a, 71b, 71c, and 71d from above in the plan view. That is, the sensor element 7 overlaps the covering layer-side surrounding wall 89 in the plan view.

The plan-view shape of the inner wall surface 891 of the covering layer-side surrounding wall 89 is a quadrilateral, and similar to that of the inner wall surface 881. In the inner wall surface 891, four wall surfaces constituting the inner wall surface 891 are respectively parallel to wall surfaces constituting the inner wall surface 881, and spaced apart from the wall surfaces constituting the inner wall surface 881 at equal intervals. For this reason, an intersection point of diagonal lines connecting opposite corners of the inner wall surface 891 in the plan view overlaps an intersection point of diagonal lines connecting opposite corners of the inner wall surface 881.

The plan-view shape of the inner wall surface 891 and the inner wall surface 881, an arrangement relationship therebetween, and the like are not limited to those described above. For example, the plan-view shape of the inner wall surface 891 and the inner wall surface 881 is a quadrilateral in the embodiment; but the plan-view shape is not limited to a quadrilateral, and may be, for example, a polygon other than a quadrilateral, a circle, or the like.

The covering layer 87 is provided on the covering layer-side surrounding wall 89 having the configuration described above.

The covering layer 87 is composed of the shielding layer 841 included in the wiring layer 84 and the sealing layer 86.

As shown in FIG. 1, the shielding layer 841 is provided so as to close an upper opening of the inter-layer insulating film 83. The shielding layer 841 is arranged so as to be contained in the reinforcing layer 821 in the plan view (refer to FIG. 2). The plan-view shape of the shielding layer 841 is a quadrilateral, and similar to that of the reinforcing layer 821 described above. An outer edge of the shielding layer 841 is parallel to an outer edge of the reinforcing layer 821, and spaced apart from edges (four edges) constituting the outer edge of the reinforcing layer 821 at equal intervals.

The shielding layer 841 includes the plurality of (9 in the embodiment) through-holes 842 at the center portion. In FIG. 2, the through-holes 842 are shown by shading.

The through-hole 842 penetrates the shielding layer 841 in the thickness direction. The plan-view shape of the through-hole 842 is a quadrilateral. The through-holes 842 are provided in a 3×3 matrix and parallel to the outer edge of the shielding layer 841. The through-holes 842 are provided spaced apart from each other with a predetermined distance. The through-holes 842 are arranged such that spaced apart distances each between the through-hole 842 and the closest through-hole 842 are equal to each other.

The through-holes 842 overlap, in the plan view, the nine through-holes 822 of the 25 through-holes 822 included in the reinforcing layer 821 described above where the nine through-holes 822 are located at the center portion of the shielding layer 841.

The sealing layer 86 is provided on the shielding layer 841 so as to cover the shielding layer 841 including the through-holes 842.

Since the element peripheral structure 8 having the configuration described above is included, contacting of the covering layer 87 with the sensor element 7 can be reduced, and the diaphragm portion 64 (a region of the substrate 6 where the sensor element 7 is arranged) can be widely secured to increase its deformation amount, in the pressure sensor 100.

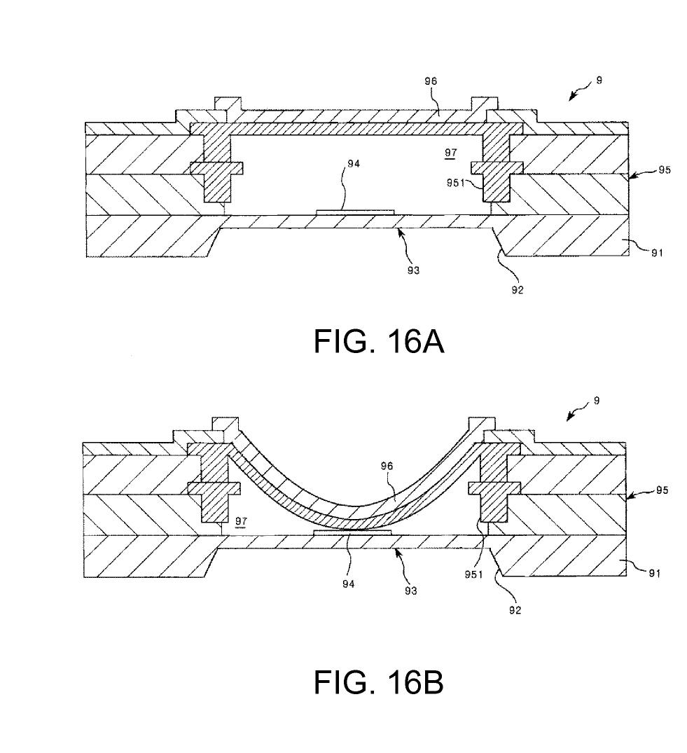

Specifically, the covering layer-side surrounding wall 89 is located on the inside of the substrate-side surrounding wall 88 as described above, and therefore, in the range that the mechanical strength of the diaphragm portion 64 is maintained, the plane area of the diaphragm portion 64 can be increased, and the plane area of a portion of the covering layer 87 covering the cavity portion 5 can be reduced. For this reason, compared to the case where the inner wall surface 891 of the covering layer-side surrounding wall 89 and the inner wall surface 881 of the substrate-side surrounding wall 88 are formed so as to substantially overlap each other in the plan view (the configuration shown in FIGS. 16A and 16B), the area of the sealing layer 86 can be reduced while securing the plane area of the diaphragm portion 64. With this configuration, the diaphragm portion 64 can be greatly deformed under pressure, and the covering layer 87 can be more effectively prevented from sagging toward the cavity portion 5 side. As a result, the pressure sensor 100 particularly has excellent sensitivity, and also has excellent stabilization in the characteristics of the sensor element 7.

The advantageous effects described above can be obtained as long as at least a portion of the covering layer-side surrounding wall 89 is located on the inside of the substrate-side surrounding wall 88 in the plan view. However, particularly when the covering layer-side surrounding wall 89 is provided such that the entire inner wall surface 891 of the covering layer-side surrounding wall 89 is contained in the inner wall surface 881 of the substrate-side surrounding wall 88 as in the embodiment, the advantageous effects described above can be remarkably exhibited.

Further, the reinforcing layer 821 is provided so as to be located between the covering layer 87 and the sensor element 7 as described above. Since the reinforcing layer 821 is included, the mechanical strength of the element peripheral structure 8 can be increased, and thus, sagging of the covering layer 87 into the cavity portion 5 can be further reduced. Particularly the strength of the element peripheral structure 8 in a direction (the horizontal direction in FIG. 1) vertical to the thickness direction of the substrate 6 can be increased. Therefore, it is possible to particularly effectively reduce sagging of the covering layer 87 toward the cavity portion 5 side caused by deflection of the covering layer 87 side of the covering layer-side surrounding wall 89 toward the cavity portion 5 side.

Moreover, even if the covering layer 87 should sag toward the cavity portion 5 side, the sagging can be stopped by the reinforcing layer 821. As a result, contacting of the covering layer 87 with the sensor element 7 can be more reliably reduced.

Moreover, the covering layer-side surrounding wall 89 is provided so as to cover the sensor element 7 in the plan view as described above. For this reason, even if a situation should occur in which not only does the covering layer 87 sag but also the reinforcing layer 821 sags, contacting of the reinforcing layer 821 with the sensor element 7 can be further reliably prevented.

Particularly when a piezoresistive element is used as the sensor element 7 as in the embodiment, it is possible to adopt a configuration in which the sensor element 7 is disposed above the edge side (in the vicinity of the inner wall surface 881 of the substrate-side surrounding wall 88) of the diaphragm portion 64. Therefore, with the use of a piezoresistive element as described above, it is easy to configure the sensor element 7 so as to be covered with the covering layer-side surrounding wall 89 in the plan view.

Moreover, the reinforcing layer 821 and the shielding layer 841 include the through-holes 822 and 842, respectively, as described above. Since the reinforcing layer 821 includes the through-holes 822, the mass of the reinforcing layer 821 can be reduced. Therefore, sagging of the reinforcing layer 821 under its own weight can be particularly effectively prevented.

Moreover, since the through-holes 822 and 842 are included, the cavity portion 5 can be easily formed by removing the inter-layer insulating films 81 and 83 located on the sensor element 7 by etching or the like through the through-holes 822 and 842. Therefore, manufacturing steps of the pressure sensor 100 can be simplified. As a result, the productivity of the pressure sensor 100 is also improved.

Moreover, the through-holes 822 and 842 in a matrix are provided in the reinforcing layer 821 and the shielding layer 841, respectively. Since the through-holes 822 included in the reinforcing layer 821 are provided in a matrix, the mechanical strength in the thickness direction does not become uneven over the entire region of the reinforcing layer 821.

Moreover, the through-holes 822 and 842 are provided in a matrix, and therefore, when the inter-layer insulating films 81 and 83 located on the sensor element 7 are removed by etching or the like through the through-holes 822 and 842 in forming of the cavity portion 5, uneven etching can be prevented, and the cavity portion 5 having a desired shape can be more easily and reliably obtained. Particularly, since the through-holes 842 overlap the through-holes 822 in the plan view as described above, the advantageous effect that can prevent uneven etching as described above can be more remarkably exhibited.

Moreover, the reinforcing layer 821 is a portion of the wiring layer 82. Therefore, the reinforcing layer 821 can be formed together with the wiring layer 82, that is, the reinforcing layer 821 and a side wall portion 823 as a portion of the wiring layer 82 except for the reinforcing layer 821 can be formed in the same step. For this reason, separate provision of a step for forming only the reinforcing layer 821 can be omitted. Therefore, the manufacturing steps of the pressure sensor 100 can be simplified. As a result, the productivity of the pressure sensor 100 is also improved.

Next, a method for manufacturing the pressure sensor 100 will be briefly described.

FIGS. 5A to 9B are diagrams showing manufacturing steps of the pressure sensor shown in FIG. 1. Hereinafter, the manufacturing steps will be described based on the drawings.

### Sensor Element Forming Step

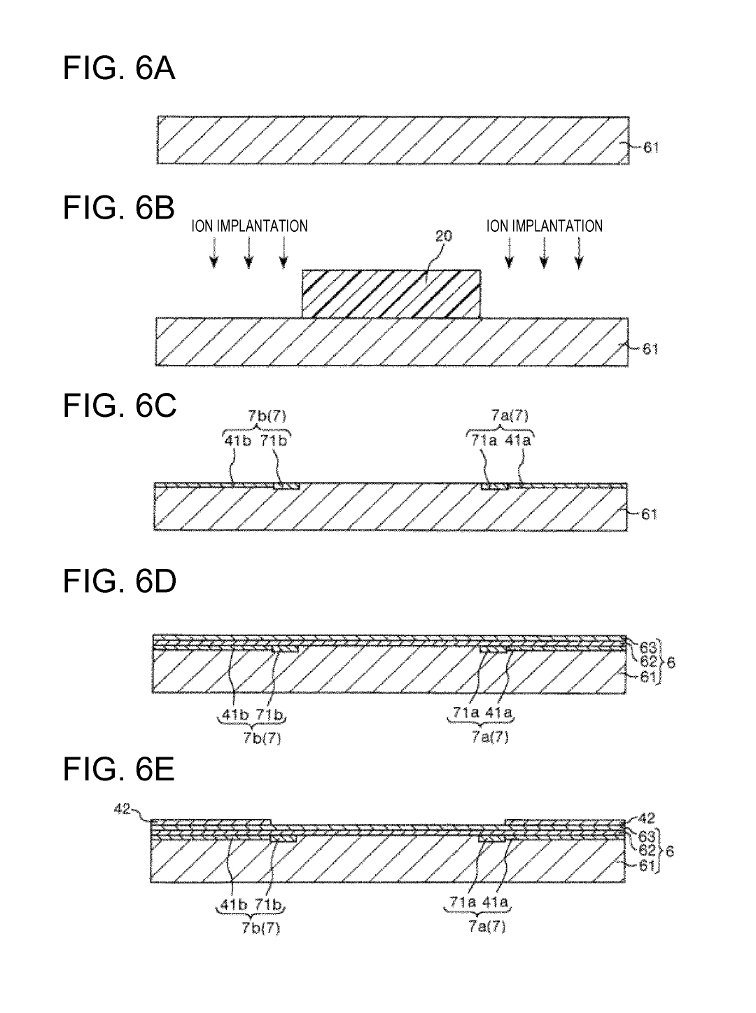

First, as shown in FIG. 6A, the semiconductor substrate 61 composed of monocrystalline silicon or the like is prepared. The thickness of a monocrystalline silicon film is not particularly limited, but the thickness is, for example, about from 400 nm to 800 nm.

Next, as shown in FIG. 6B, a photoresist film 20 is formed on the semiconductor substrate 61 so as to expose a portion of the semiconductor substrate 61. Thereafter, by doping (ion implanting) an impurity such as phosphorus or boron into the exposed portion (place where the piezoresistive elements 7a, 7b, 7c, and 7d can be formed) of the semiconductor substrate 61, the sensor element 7 is formed as shown in FIG. 6C.

In the ion implantation, the shape of the photoresist film 20, ion implantation conditions, and the like are adjusted such that the doping amount of impurity into the connecting portions 73c and 73d and the wires 41a, 41b, 41c, and 41d is higher than the doping amount of impurity into the piezoresistive portions 71a, 71b, 71c, and 71d.

For example, when boron ion implantation at 17 keV is performed, the concentration of ions implanted into the piezoresistive portions 71a, 71b, 71c, and 71d is about from 1×10¹³ atoms/cm² to 1×10²⁵ atoms/cm², and the concentration of ions implanted into the connecting portions 73c and 73d and the wires 41a, 41b, 41c, and 41d is about from 1×10¹⁵ atoms/cm² to 5×10¹⁵ atoms/cm².

Next, as shown in FIG. 6D, a top surface of the semiconductor substrate 61 is thermally oxidized to thereby form the silicon oxide film (insulating film) 62. Further, the silicon nitride film 63 is formed on the silicon oxide film 62 by a sputtering method, a CVD method, or the like. With this configuration, the substrate 6 is obtained.

Next, as shown in FIG. 6E, a polycrystalline silicon film is formed on the silicon nitride film 63 by a sputtering method, a CVD method, or the like, and the polycrystalline silicon film is patterned by etching to obtain the layer 42.

### Inter-layer Insulating Film and Wiring Layer Forming Step

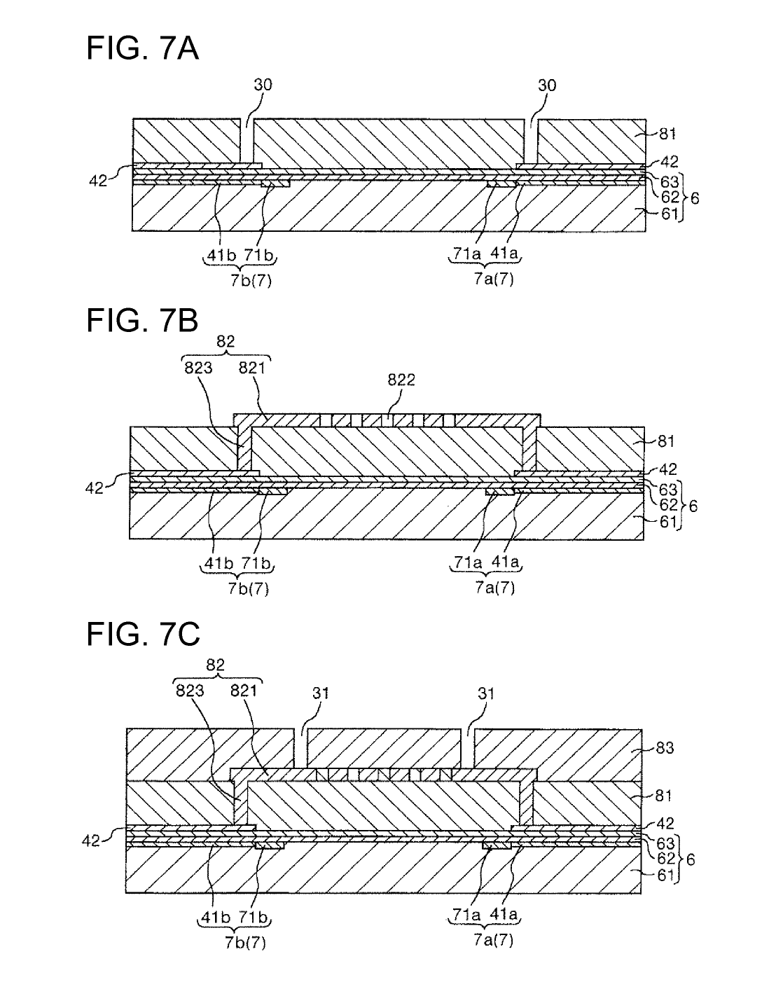

As shown in FIG. 7A, the inter-layer insulating film 81 formed of a silicon oxide film is formed on the silicon nitride film 63 by a sputtering method, a CVD method, or the like. Moreover, an annular shaped opening 30 surrounding the sensor element 7 in the plan view of the substrate 6 is formed in the inter-layer insulating film 81 by a patterning process or the like.

Next, as shown in FIG. 7B, a layer formed of, for example, aluminum is formed on the inter-layer insulating film 81 by a sputtering method, a CVD method, or the like, and then processed by patterning to thereby form the wiring layer 82. The wiring layer 82 (the side wall portion 823 except for the reinforcing layer 821) has an annular shape in the plan view of the substrate 6 so as to correspond to the opening 30. Moreover, a portion of the wiring layer 82 is located above the sensor element 7, and constitutes the reinforcing layer 821 in which the plurality of through-holes 822 are formed.

Moreover, a portion of the wiring layer 82 is electrically connected to wires (for example, the wires 41a, 41b, 41c, and 41d or wires constituting a portion of the semiconductor circuit (not shown)) formed on and above the semiconductor substrate 61 through the opening 30. The wiring layer 82 is formed as if it is present only at a portion surrounding the sensor element 7. In general, however, a portion of a wiring layer constituting a portion of the semiconductor circuit (not shown) constitutes the wiring layer 82.

Next, as shown in FIG. 7C, the inter-layer insulating film 83 formed of a silicon oxide film or the like is formed on the inter-layer insulating film 81 and the wiring layer 82 by a sputtering method, a CVD method, or the like. Moreover, an annular shaped opening 31 surrounding the sensor element 7 in the plan view of the substrate 6 is formed in the inter-layer insulating film 83 by a patterning process or the like. The opening 31 may not have an annular shape in the plan view of the semiconductor substrate 61 similarly to the opening 30, or a portion of the opening 31 may be omitted.

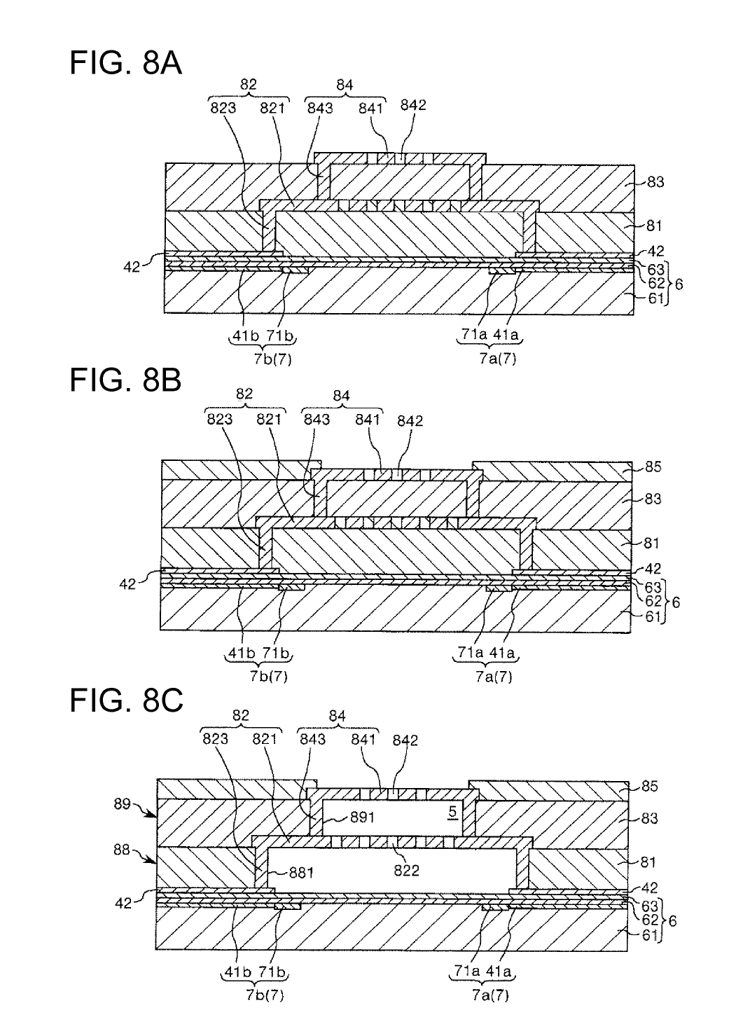

Next, as shown in FIG. 8A, a layer formed of, for example, aluminum is formed on the inter-layer insulating film 83 and the wiring layer 84 by a sputtering method, a CVD method, or the like, and then processed by patterning to thereby form the wiring layer 84. The wiring layer 84 (the side wall portion 843 except for the shielding layer 841) has an annular shape in the plan view of the substrate 6 so as to correspond to the opening 31. Moreover, a portion of the wiring layer 84 is located above the sensor element 7, and constitutes the shielding layer 841 in which the plurality of through-holes 842 are formed.

In general, also the wiring layer 84 is composed of a portion of a wiring layer constituting a portion of the semiconductor circuit (not shown) similarly to the wiring layer 82 described above.

The stacked structure of inter-layer insulating films and wiring layers is formed by a common CMOS process, and the number of stacked layers is appropriately set as necessary. That is, more wiring layers may be stacked as necessary via an inter-layer insulating film.

The thickness of each of the inter-layer insulating films 81 and 83 obtained is not particularly limited, but the thickness is, for example, about from 300 nm to 5000 nm. The thickness of each of the wiring layers 82 and 84 is not particularly limited, but the thickness is, for example, about from 300 nm to 1000 nm.

### Cavity Portion Forming Step

Next, as shown in FIG. 8B, the surface protective layer 85 is formed by a sputtering method, a CVD method, or the like, and then, the cavity portion 5 is formed by etching as shown in FIG. 8C.

The surface protective layer 85 is composed of a plurality of film layers including one or more kinds of materials, and is formed so as not to seal the through-holes 842 of the shielding layer 841. As to the constituent material of the surface protective layer 85, the surface protective layer 85 is formed of a material having resistance for protecting the element from moisture, dust, flaw, or the like, such as a silicon oxide film, a silicon nitride film, a polyimide film, or an epoxy resin film. The thickness of the surface protective layer 85 is not particularly limited, but the thickness is, for example, about from 300 nm to 5000 nm.

The formation of the cavity portion 5 is performed by removing portions of the inter-layer insulating films 81 and 83 by etching through the plurality of through-holes 822 formed in the reinforcing layer 821 and the plurality of through-holes 842 formed in the shielding layer 841. In this case, when wet etching is used for the etching, an etchant such as hydrofluoric acid or buffered hydrofluoric acid is supplied through the plurality of through-holes 842; and when dry etching is used, an etching gas such as hydrofluoric acid gas is supplied through the plurality of through-holes 842.

By forming the cavity portion 5 as described above, the substrate-side surrounding wall 88 and the covering layer-side surrounding wall 89 are obtained.

### Sealing Layer Forming Step

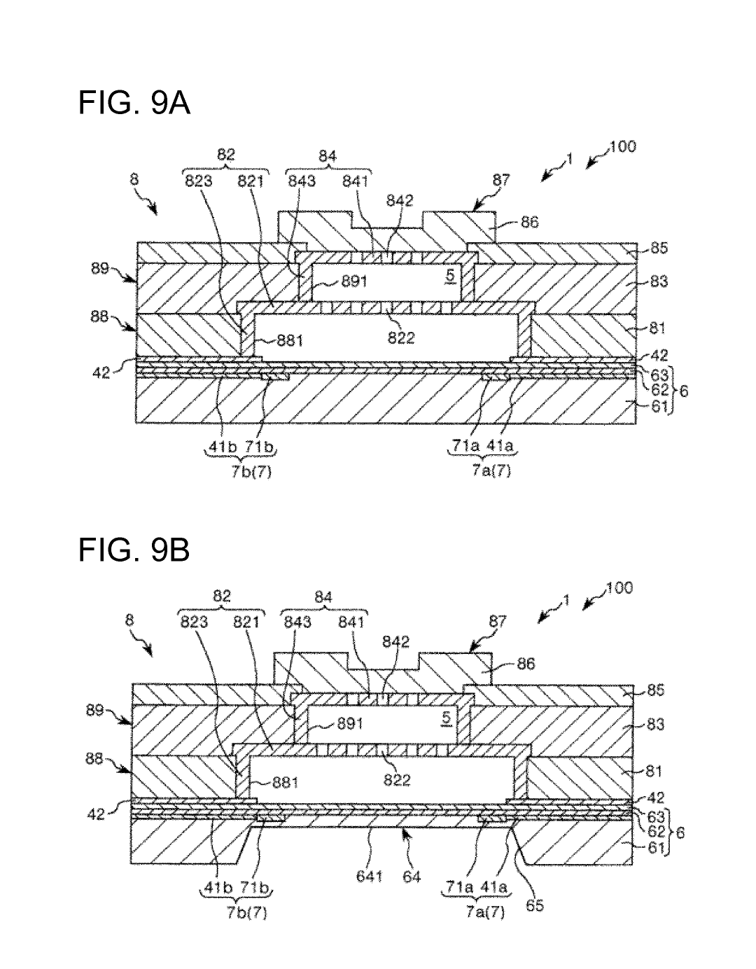

Next, as shown in FIG. 9A, the sealing layer 86 formed of a silicon oxide film, a silicon nitride film, or a metal film such as Al, Cu, W, Ti, or TiN is formed on the shielding layer 841 by a sputtering method, a CVD method, or the like to seal the through-holes 842. With this configuration, the covering layer 87 including the shielding layer 841 and the sealing layer 86 is obtained. In this manner, the MEMS device 1 is formed.

The thickness of the sealing layer 86 is not particularly limited, but the thickness is, for example, about from 1000 nm to 5000 nm.

### Diaphragm Forming Step

Finally, a lower surface of the semiconductor substrate 61 is grinded to obtain the semiconductor substrate 61 that is entirely thinned. Thereafter, as shown in FIG. 9B, a portion of the lower surface of the thinned semiconductor substrate 61 is removed by, for example, dry etching. With this configuration, the pressure sensor 100 in which the diaphragm portion 64 that is thinner than the peripheral portion is formed is obtained.

The removal thickness of the semiconductor substrate 61 through grinding is not particularly limited, but the thickness is, for example, about from 100 μm to 600 μm.

The method of removing a portion of the lower surface of the semiconductor substrate 61 is not limited to dry etching, and may be wet etching or the like. Moreover, when the diaphragm portion 64 includes a portion of the semiconductor substrate 61, the thickness of the semiconductor substrate 61 at the portion is about 80 μm or less.

Through the steps described above, the pressure sensor 100 can be manufactured.

Although not shown in the drawings, the circuit elements, such as MOS transistors, active elements, capacitors, inductors, resistors, diodes, and wires, included in the semiconductor circuit can be fabricated in the appropriate step (for example, the sensor element forming step, the inter-layer insulating film and wiring layer forming step, or the sealing layer forming step) described above. For example, an isolation film between circuit elements can be formed together with the silicon oxide film 62; a gate electrode, a capacitor electrode, a wire, or the like can be formed together with the sensor element 7; a gate insulating film, a capacitor dielectric layer, or an inter-layer insulating film can be formed together with the inter-layer insulating films 81 and 83; and a wire in the circuit can be formed together with the wiring layers 82 and 84.

### Second Embodiment

Next, a second embodiment of the pressure sensor including the MEMS device according to the invention will be described.

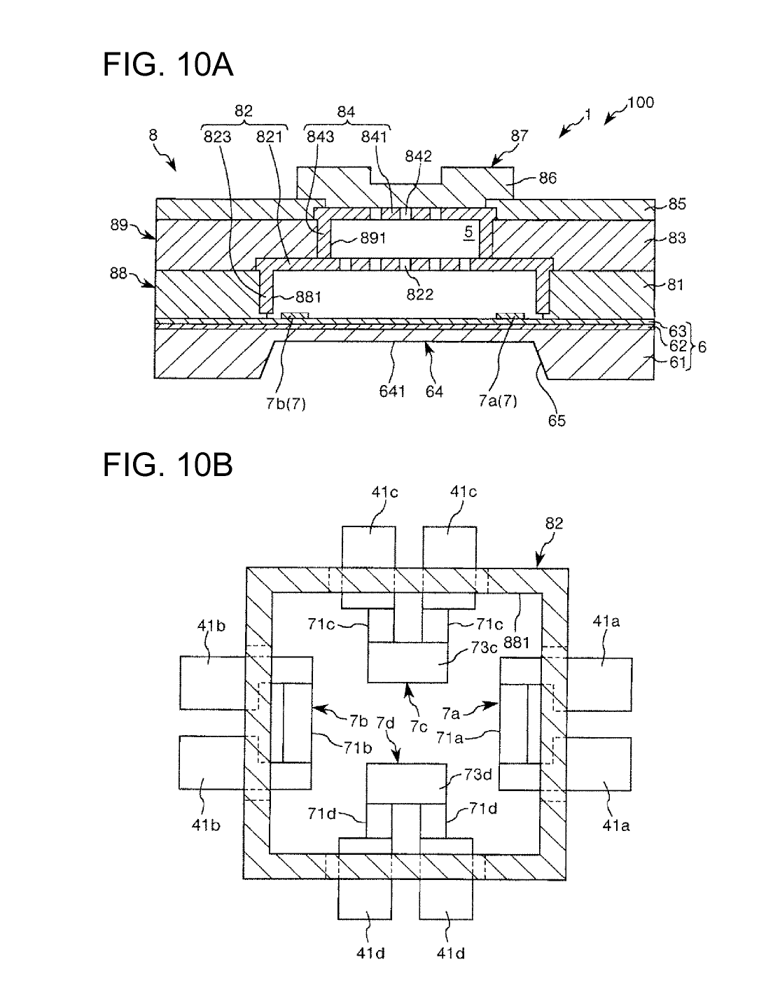

FIGS. 10A and 10B are cross-sectional views showing the second embodiment of the pressure sensor including the MEMS device according to the invention.

Hereinafter, the second embodiment of the pressure sensor according to the invention will be described, in which differences from the embodiment described above are mainly described, and similar matters are not described.

The second embodiment is similar to the first embodiment, except that the configuration of the diaphragm portion and the arrangement of the sensor element are different.

The diaphragm portion 64 included in the pressure sensor 100 shown in FIG. 10A is composed of the semiconductor substrate 61, the silicon oxide film 62, and the silicon nitride film 63.

Specifically, the substrate 6 included in the pressure sensor 100 is composed of the semiconductor substrate 61 composed of semiconductor such as silicon, the silicon oxide film 62 provided on one of surfaces of the semiconductor substrate 61, and the silicon nitride film 63 provided on the silicon oxide film 62. In this case, both the silicon oxide film 62 and the silicon nitride film 63 can be used as insulating films. One of these insulating films can be omitted depending on a forming method of the element peripheral structure 8, or the like. The diaphragm portion 64 is composed of three layers of a thinned portion of the semiconductor substrate 61, the silicon oxide film 62, and the silicon nitride film 63.

The recess 65 does not penetrate the semiconductor substrate 61, and the diaphragm portion 64 is composed of a portion of the semiconductor substrate 61 that is thinned with the recess 65, the silicon oxide film 62, and the silicon nitride film 63.

The recess 65 may penetrate the semiconductor substrate 61, and the diaphragm portion 64 may be composed of two layers of the silicon oxide film 62 and the silicon nitride film 63. The diaphragm portion 64 having this configuration can be extremely thinned, and therefore, the sensitivity of the pressure sensor 100 can be extremely increased. Moreover, these films can be used as etching stop layers in etching when forming the recess 65 by etching. Therefore, variations in the thickness of the diaphragm portion 64 among products can be reduced.

As shown in FIG. 10A, the sensor element 7 is disposed above the diaphragm portion 64. The sensor element 7 is composed of the plurality of piezoresistive elements 7a, 7b, 7c, and 7d. Similarly to the first embodiment, the piezoresistive elements 7a, 7b, 7c, and 7d include the piezoresistive portions 71a, 71b, 71c, and 71d, the connecting portions 73c and 73d, and the wires 41a, 41b, 41c, and 41d.

The piezoresistive portions 71a, 71b, 71c, and 71d are composed of, for example, polysilicon (polycrystalline silicon) into which an impurity such as phosphorus or boron is doped (diffused or implanted). The connecting portions 73c and 73d of the piezoresistive elements 7c and 7d and the wires 41a, 41b, 41c, and 41d are each composed of, for example, polysilicon (polycrystalline silicon) into which an impurity such as phosphorus or boron is doped (diffused or implanted) at a higher concentration than the piezoresistive portions 71a, 71b, 71c, and 71d.

Also with the pressure sensor 100 described above, sagging of the covering layer 87 toward the substrate 6 side can be reduced, and therefore, contacting of the covering layer 87 with the sensor element 7 can be more effectively reduced.

### Third Embodiment

Next, a third embodiment of the pressure sensor including the MEMS device according to the invention will be described.

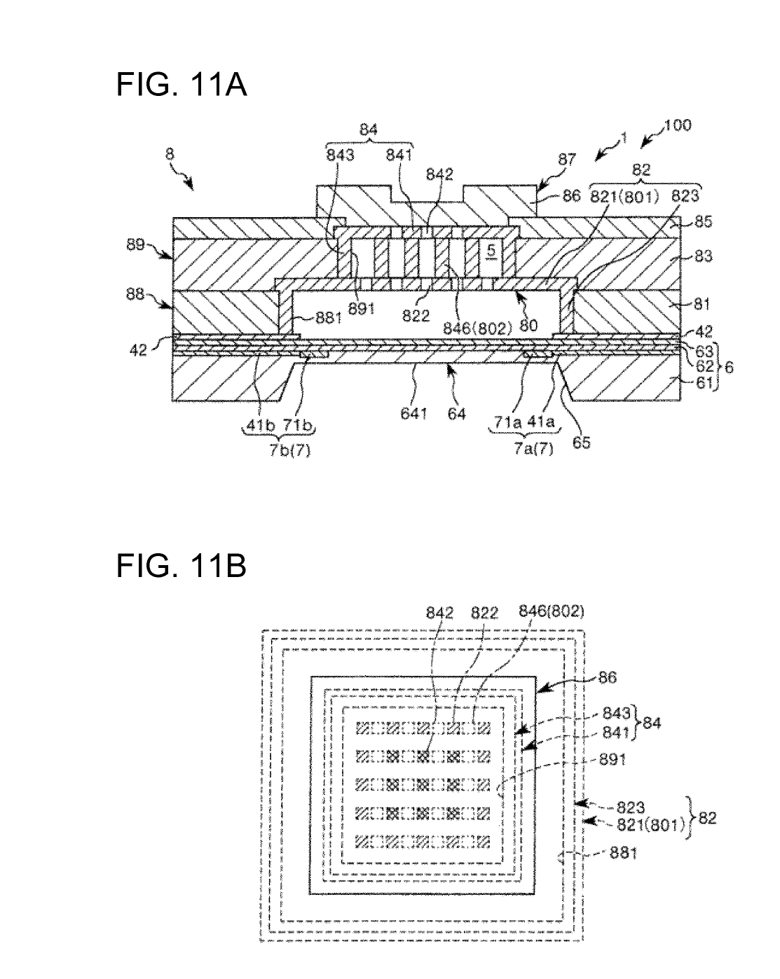

FIGS. 11A and 11B are cross-sectional views showing the third embodiment of the pressure sensor including the MEMS device according to the invention.

Hereinafter, the third embodiment of the pressure sensor according to the invention will be described, in which differences from the embodiment described above are mainly described, and similar matters are not described.

The third embodiment is similar to the first embodiment, except that the configuration of the reinforcing layer included in the element peripheral structure is different.

A reinforcing layer 80 included in the pressure sensor 100 shown in FIGS. 11A and 11B includes a first reinforcing layer (reinforcing portion) 801 provided on the inter-layer insulating film 81 and a second reinforcing layer (reinforcing portion) 802 provided on the first reinforcing layer 801.

Similarly to the first embodiment, the first reinforcing layer 801 is composed of the reinforcing layer 821 including the plurality of fine pores (through-holes) 822.

The second reinforcing layer 802 is provided on the first reinforcing layer 801, and composed of a plurality of reinforcing pillars 846. The entire shape of the reinforcing pillar 846 is cubic, that is, prism-shaped. In the embodiment, reinforcing pillars 846 are provided such that the longitudinal direction of the reinforcing pillar 846 is parallel to the thickness direction of the wiring layer 84. Moreover, one end of the reinforcing pillar 846 is connected to the first reinforcing layer 801, while the other end is connected to the covering layer 87 (specifically, the shielding layer 841).

Moreover, the reinforcing pillars 846 are provided at the center portion of the first reinforcing layer 801 in the plan view, and arranged in a 4×5 matrix. Specifically, the reinforcing pillar 846 is provided between the through-holes 822 included in the first reinforcing layer 801 (the reinforcing layer 821). The arrangement, shape, and the like of the reinforcing pillars 846 are not limited to the configuration shown in the embodiment.

Also with the pressure sensor 100 described above, sagging of the covering layer 87 toward the substrate 6 side can be reduced, and therefore, contacting of the covering layer 87 with the sensor element 7 can be more effectively reduced.

Particularly in the pressure sensor 100 of the embodiment, since the reinforcing pillars 846 (the second reinforcing layer 802) function as members that reinforce the mechanical strength of the covering layer 87 in the thickness direction, sagging of the covering layer 87 toward the cavity portion 5 side can be more effectively reduced.

### Fourth Embodiment

Next, a fourth embodiment of the pressure sensor including the MEMS device according to the invention will be described.

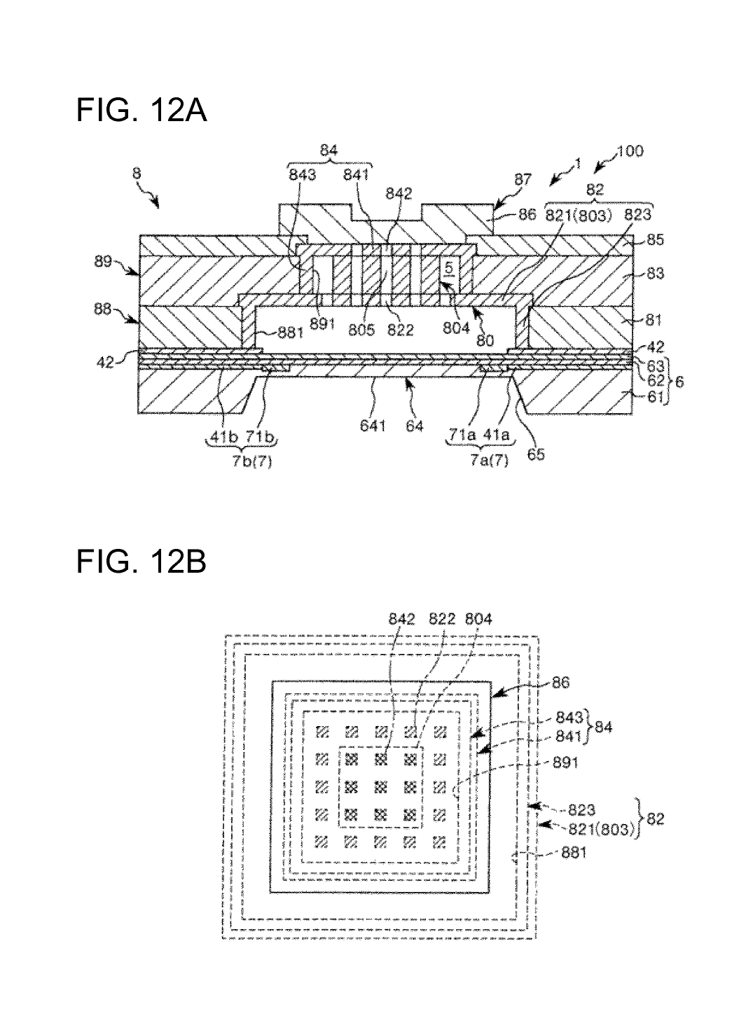

FIGS. 12A and 12B are cross-sectional views showing the fourth embodiment of the pressure sensor including the MEMS device according to the invention.

Hereinafter, the fourth embodiment of the pressure sensor according to the invention will be described, in which differences from the embodiment described above are mainly described, and similar matters are not described.

The fourth embodiment is similar to the first embodiment, except that the configuration of the reinforcing layer included in the element peripheral structure is different.

The reinforcing layer 80 included in the pressure sensor 100 shown in FIGS. 12A and 12B includes a first reinforcing layer (reinforcing portion) 803 provided on the inter-layer insulating film 81 and a second reinforcing layer (reinforcing portion) 804 provided on the first reinforcing layer 803.

Similarly to the first embodiment, the first reinforcing layer 803 is composed of the reinforcing layer 821 including the plurality of fine pores (through-holes) 822.

The second reinforcing layer 804 is provided on the first reinforcing layer 803. Moreover, the second reinforcing layer 804 is connected to the first reinforcing layer 803 and the covering layer 87 (specifically, the shielding layer 841).

The plan-view shape of the second reinforcing layer 804 is grid-like, and the second reinforcing layer 804 includes a plurality of (nine in the embodiment) through-holes 805. The through-hole 805 is in communication with the through-hole 822 and the through-hole 842 provided in the shielding layer 841.

Also with the pressure sensor 100 described above, sagging of the covering layer 87 toward the substrate 6 side can be reduced, and therefore, contacting of the covering layer 87 with the sensor element 7 can be more effectively reduced.

Particularly in the pressure sensor 100 of the embodiment, since the second reinforcing layer 804 is included, the mechanical strength of the covering layer 87 in the thickness direction can be further increased. For this reason, sagging of the covering layer 87 toward the cavity portion 5 side can be further effectively reduced.

### 2. Altimeter

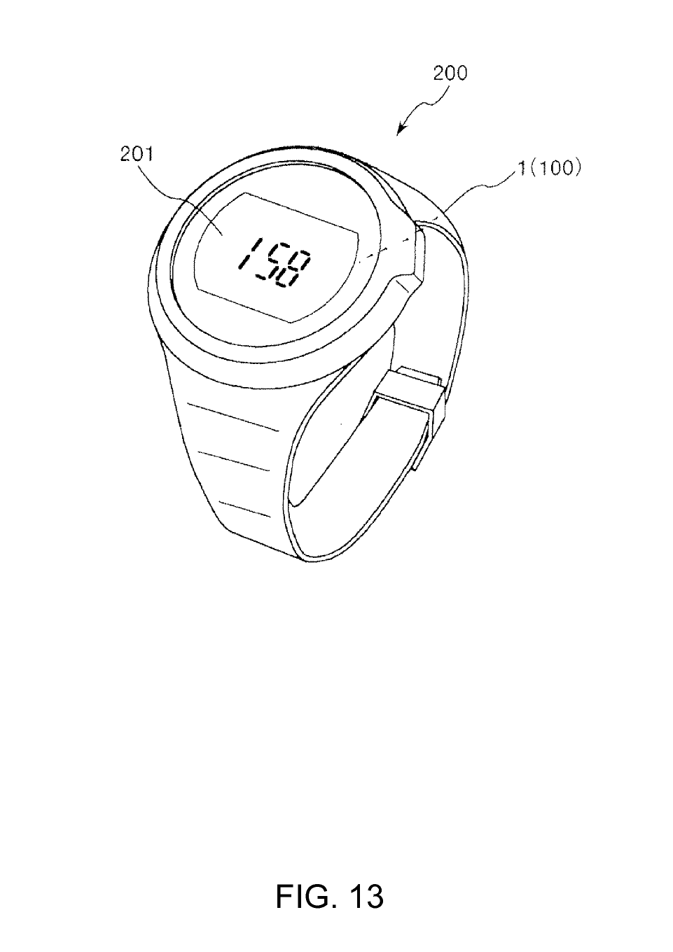

Next, an example of an altimeter (altimeter according to the invention) including the MEMS device according to the invention will be described. FIG. 13 is a perspective view showing the example of the altimeter according to the invention.

An altimeter 200 can be worn on the wrist like a wristwatch. The MEMS device 1 (the pressure sensor 100) is mounted in the altimeter 200, so that the altitude of a current location above sea level, the air pressure of a current location, and the like can be displayed on a display portion 201.

On the display portion 201, various information such as a current time, a user's heart rate, and weather can be displayed.

### 3. Electronic Apparatus

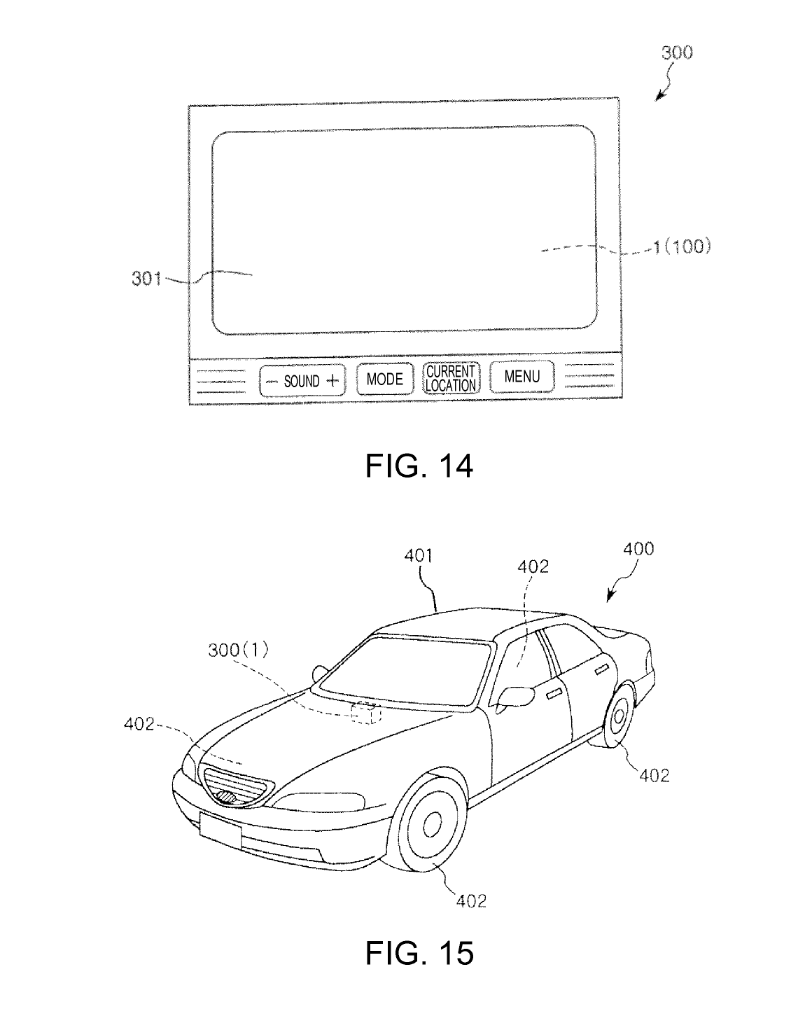

Next, a navigation system to which an electronic apparatus including the MEMS device (the pressure sensor 100) according to the invention is applied will be described. FIG. 14 is an elevation view showing an example of the electronic apparatus according to the invention.

A navigation system 300 includes map information (not shown), a position information acquiring unit that acquires position information from a global positioning system (GPS), a self-contained navigation unit using a gyro sensor, an acceleration sensor, and vehicle speed data, the MEMS device 1 (the pressure sensor 100), and a display portion 301 that displays predetermined position information or course information.

According to the navigation system, altitude information can be acquired in addition to acquired position information. For example, when a car runs on an elevated road indicated on position information at substantially the same position as an open road, the navigation system cannot determine, in the absence of altitude information, whether the car runs on the open road or the elevated road, and therefore, the navigation system provides the user with information on the open road as preferential information. Therefore, in the navigation system 300 according to the embodiment, altitude information can be acquired by the MEMS device 1 (the pressure sensor 100), a change in altitude due to the car entering the elevated road from the open road is detected, and it is possible to provide the user with navigation information in a running state on the elevated road.

The display portion 301 is composed of, for example, a liquid crystal panel display or an organic electro-luminescence (EL) display, so that reductions in size and thickness are possible.

The electronic apparatus including the MEMS device according to the invention is not limited to that described above, and can be applied to, for example, personal computers, mobile phones, medical apparatuses (for example, electronic thermometers, sphygmomanometers, blood glucose meters, electrocardiogram measuring systems, ultrasonic diagnosis apparatuses, and electronic endoscopes), various kinds of measuring instrument, indicators (for example, indicators used in vehicles, aircraft, and ships), and flight simulators.

### 4. Moving Object

Next, a moving object (moving object according to the invention) to which the MEMS device according to the invention is applied will be described. FIG. 15 is a perspective view showing an example of the moving object according to the invention.

As shown in FIG. 15, a moving object 400 includes a car body 401 and four wheels 402, and is configured to rotate the wheels 402 with a source of power (engine) (not shown) provided in the car body 401. Into the moving object 400, the navigation system 300 (the MEMS device 1) is built.

The MEMS device, the pressure sensor, the altimeter, the electronic apparatus, and the moving object according to the invention have been described above based on the embodiments shown in the drawings, but the invention is not limited to the embodiments. The configuration of each part can be replaced with any configuration having a similar function. Moreover, any other configurations or steps may be added to the embodiments.

Although an example of using a piezoresistive element as a sensor element has been described in the embodiment described above, the invention is not limited to the example. For example, a functional element including a vibrating element such as other MEMS vibrators like a flap-type vibrator or an inter-digital electrode, or a quartz crystal vibrator can also be used.

Although an example of using four sensor elements has been described in the embodiment described above, the invention is not limited to the example. The number of sensor elements may be from one to three, or five or more.

Although an example in which the sensor element is disposed above the surface side opposite to the pressure receiving surface of the diaphragm portion has been described in the embodiment described above, the invention is not limited to the example. For example, the sensor element may be disposed above the pressure receiving surface side of the diaphragm portion, or the sensor element may be disposed above both surfaces of the diaphragm portion.

Although an example in which the sensor element is disposed above the perimeter portion side of the diaphragm portion has been described in the embodiment described above, the invention is not limited to the example. The sensor element may be arranged at the center portion of the diaphragm portion.

The entire disclosure of Japanese Patent Application No. 2014-018074, filed Jan. 31, 2014 is expressly incorporated by reference herein.

What is claimed is:

1. A MEMS device comprising:
a substrate;
a functional element that is disposed above the substrate;
a surrounding wall that is disposed above one surface side of the substrate and surrounds the functional element in a plan view;
a covering layer that overlaps the substrate in the plan view and is connected to the surrounding wall; and
a reinforcing layer that is arranged between the covering layer and the functional element, wherein
the surrounding wall includes
a substrate-side surrounding wall, and
a covering layer-side surrounding wall that is located on the covering layer side of the substrate-side surrounding wall and at least a portion of which is disposed above the inside of the substrate-side surrounding wall in the plan view.

2. The MEMS device according to claim 1, wherein the reinforcing layer includes a through-hole that penetrates the reinforcing layer in a thickness direction thereof.

3. The MEMS device according to claim 1, wherein the reinforcing layer is connected to the covering layer.

4. The MEMS device according to claim 1, wherein the substrate includes a diaphragm portion that is deflected and deformed under pressure and at least a portion of which overlaps the covering layer in the plan view.

5. The MEMS device according to claim 1, wherein at least a portion of the functional element overlaps the covering layer-side surrounding wall in the plan view.

6. The MEMS device according to claim 1, wherein the functional element includes a piezoresistive element.

7. The MEMS device according to claim 1, wherein the plan-view shape of the reinforcing layer includes a grid-like portion.

8. A pressure sensor comprising the MEMS device according to claim 1.

9. An altimeter comprising the MEMS device according to claim 1.

10. An electronic apparatus comprising the MEMS device according to claim 1.

11. A moving object comprising the MEMS device according to claim 1.
